(19) United States
(12) Patent Application Publication
(10) Pub. No.: US 2015/0371962 A1
(43) Pub. Date: Dec. 24, 2015

(54) TERMINAL STRUCTURE, SEMICONDUCTOR DEVICE, AND TERMINAL FORMING METHOD

(71) Applicant: FUJITSU LIMITED, Kawasaki-shi (JP)

(72) Inventor: TOSHIYA AKAMATSU, Zama (JP)

(73) Assignee: FUJITSU LIMITED, Kawasaki (JP)

(21) Appl. No.: 14/734,267

(22) Filed: Jun. 9, 2015

(30) Foreign Application Priority Data
Jun. 20, 2014 (JP) 2014-126887

(51) Int. Cl. H01L 23/00

(52) U.S. Cl. CPC H01L 24/13; H01L 24/11; H01L 2224/13166; H01L 2224/13171; H01L 2224/13181; H01L 2224/13124; H01L 2224/13184; H01L 2224/1318; H01L 2224/13147; H01L 2224/13611; H01L 2224/13155; H01L 2924/3512; H01L 2224/13016; H01L 2224/13082; H01L 2224/13562; H01L 2224/13582

(57) ABSTRACT

A terminal structure includes: a pillar containing a first metal material; and a cover layer covering an upper surface and a side surface of the pillar, the cover layer containing a second metal material into which a solder material diffuses more slowly than into the first metal material.

And the terminal structure further includes a bonding layer over the cover layer, the bonding layer containing a metal material capable of solder bonding.

### CROSS-REFERENCE TO RELATED APPLICATION

This application is based upon and claims the benefit of priority of the prior Japanese Patent Application No. 2014-126887, filed on Jun. 20, 2014, the entire contents of which are incorporated herein by reference.

### FIELD

The embodiments discussed herein are related to a terminal structure, a semiconductor device, and a terminal forming method.

### BACKGROUND

Electronic apparatuses are desired to have higher functionality (high speed, large capacity) as well as to be smaller and to consume smaller power. For the connection between semiconductor chips or between a semiconductor chip and a substrate, in general, terminals arranged on the periphery of the semiconductor chip are connected by wire bonding. In recent years, with the increasing number of terminals, the terminals are often connected by flip-chip bonding that is performed in such a manner that terminals to be connected to each other on the surfaces of semiconductor chips and a substrate are opposed to each other. This technique enables the connection of a larger number of terminals and leads to enhanced performance.

For example, for flip-chip bonding of a semiconductor chip on a substrate, copper pillars are formed as terminals on the surfaces of the semiconductor chip and the substrate, and solder-bonded with being opposed to each other. Also, it has been devised that a barrier layer is formed over the top of the copper pillar to block copper diffusing from the copper pillar.

When metal pillars are solder-bonded with being opposed to each other for flip-chip bonding, the solider material may diffuse into the metal material of the pillar and react to produce a compound of the metal material of the pillar and the solder material at the bonded portion. This may degrade the reliability of bonding, and, for example, reduce strength. It may be effective in avoiding this phenomenon to form a diffusion barrier layer over the top of the metal pillar as mentioned above.

However, it has been found that if solder-bonded pillars receives a thermal load, for example, for high temperature storage test, the solder material migrates to the side surface of the pillar due to solid-phase diffusion at the surface and thereby decreases in amount in the bonded portion. This may result in bonding failure such as a break in the bonded portion and thus reduce the reliability of bonding. Accordingly, it is desirable to keep solder material from diffusing into the side surface of the pillar containing a metal material after being solder-bonded and thus to improve the reliability of bonding.

The followings are reference documents:

### [Document 1] Japanese Laid-open Patent Publication No. 2013-131782,

### [Document 2] Japanese Laid-open Patent Publication No. 2002-203925, and

### [Document 3] Japanese Laid-open Patent Publication No. 2006-295109.

### SUMMARY

According to an aspect of the invention, a terminal structure includes: a pillar containing a first metal material; and a cover layer covering an upper surface and a side surface of the pillar, the cover layer containing a second metal material into which a solder material diffuses more slowly than into the first metal material.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a schematic sectional view of a terminal structure according to an embodiment;

FIGS. 2A-2C are schematic sectional views of terminal structures according to some embodiments;

FIG. 3 is a schematic sectional view of a terminal structure according to an embodiment;

FIGS. 4A-4D are schematic sectional views of terminal structures according to some embodiments;

FIG. 5 is a schematic sectional view of a terminal structure according to an embodiment;

FIG. 6 is a schematic sectional view of a terminal structure according to an exemplary embodiment;

FIG. 7 is a schematic sectional view illustrating the effect of a terminal structure according to an exemplary embodiment;

FIGS. 8A-8C are schematic sectional views illustrating a problem to be solved by an embodiment;

FIGS. 9A-9C are schematic sectional views illustrating a problem to be solved by an embodiment;

FIGS. 10A-10D are schematic sectional views illustrating a problem to be solved by an embodiment;

FIGS. 11A-11F are schematic sectional views illustrating a method for forming terminals (first terminal forming method) according to an embodiment;

FIGS. 12A-12E are schematic sectional views illustrating the method for forming terminals (first terminal forming method) according to an embodiment;

FIGS. 13A-13D are schematic sectional views illustrating a semiconductor component (semiconductor device) according to an embodiment and a method for manufacturing the same;

FIGS. 14A-14G are schematic views illustrating a semiconductor component according to an embodiment, a method for manufacturing the same, and an electronic apparatus;

FIGS. 15A-15F are schematic sectional views illustrating a method for forming terminals (second terminal forming method) according to an embodiment;

FIGS. 16A-16F are schematic sectional views illustrating the method for forming terminals (second terminal forming method) according to an embodiment;

FIGS. 17A-17F are schematic sectional views illustrating a method for forming terminals (third terminal forming method) according to an embodiment;

FIGS. 18A-18E are schematic sectional views illustrating the method for forming terminals (third terminal forming method) according to an embodiment;

FIGS. 19A-19F are schematic sectional views illustrating a method for forming terminals (fourth terminal forming method) according to an embodiment; and

FIGS. 20A-20G are schematic sectional views illustrating the method for forming terminals (fourth terminal forming method) according to an embodiment.

### DESCRIPTION OF EMBODIMENTS

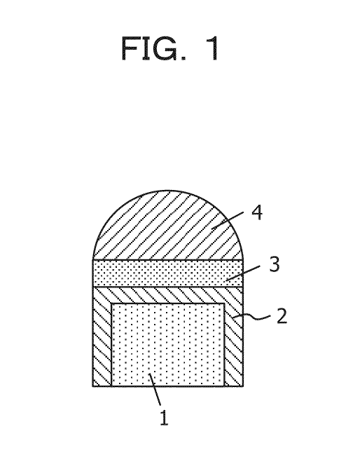

The terminal structure, semiconductor device, electronic apparatus and terminal forming method according to exemplary embodiments will now be described with reference to FIGS. 1 to 20G. A terminal structure of an embodiment is formed in a semiconductor element such as a semiconductor chip (for example, LSI chip) or a semiconductor wafer, or on a substrate, such as a circuit board, a wiring board, a package substrate or a build-up board, and is used for flip-chip bonding connection.

The terminal structure is suitable for terminals formed on the surfaces of semiconductor elements of a semiconductor component, such as a CMOS LSI, a memory device, a sensor device or an MEMS, and used for connecting the semiconductor elements to each other. The terminal may be referred to as protruding terminal, columnar terminal, connection terminal, electrode, electrode terminal, protruding electrode, columnar electrode, protrusion electrode, or columnar bump. Also, the terminal structure may be referred to as connection terminal structure, electrode structure, or electrode terminal structure. A semiconductor element, such as a semiconductor chip or a semiconductor wafer, and a semiconductor component including semiconductor elements connected each other may be referred to as a semiconductor device.

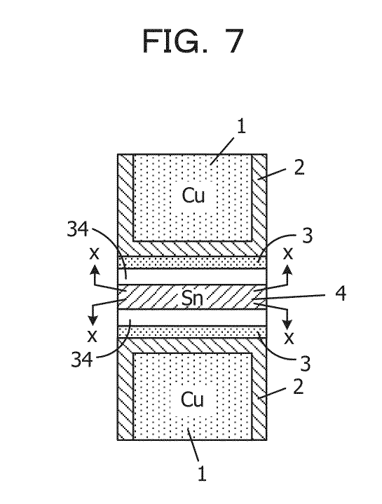

As illustrated in FIGS. 1 to 4D, the terminal structure includes a pillar 1 containing a first metal material, and a cover layer 2 covering the upper and side surfaces of the pillar 1 and containing a second metal material into which solder material will diffuse more slowly than into the first metal material. This structure keeps the solder material from diffusing into the side surface of the pillar 1 after the terminal has been solder-bonded, thus enhancing the reliability of bonding (see FIG. 7). A solder layer 4 may be disposed right above the cover layer 2, as illustrated in FIGS. 1, 2C, 4C, and 4D.

Preferably, the pillar 1 contains Cu as the first metal material. For example, the pillar 1 is made of Cu or a Cu alloy. The pillar 1 may be referred to as the pillar bump or metal pillar. The first metal material may be referred to as the pillar material, electrode material or electrode terminal material. Preferably, the solder material contains Sn. If the solder layer 4 is formed right above the cover layer 2 (see FIGS. 1, 2C, 4C, and 4D), the solder material of the solder layer 4 preferably contains Sn.

Examples of the solder material include Sn—Ag alloys such as Sn-3.5Ag (Ag content: about 0.5 to about 4.5), Sn—Cu alloys such as Sn-0.7Cu, Sn—Ag—Cu alloys such as Sn-3Ag-0.5Cu, Sn-1.0Ag-0.7Cu, Sn-0.3Ag-0.7Cu, and Sn-0.1Ag-0.7Cu, Sn—Sb alloys such as Sn-5Sb, Sn—Pb alloys such as Sn-37Pb, Sn—Zn alloys such as Sn-8Zn, In-based alloys such as In-48Sn, and Bi-based alloys such as Sn-58Bi and Sn-57Bi-1Ag.

Preferably, the cover layer 2 contains a metal selected from the group consisting of Ti, Cr, Ta, Al, W and Mo as the second metal material. For example, the cover layer 2 is made of Ti, Cr, Ta, Al, W or Mo, or an alloy containing any one of these metals (an alloy mainly containing these metals). The second metal material of the cover layer 2 does not react with the solder material to produce an alloy. The second metal material may be referred to as the cover material.

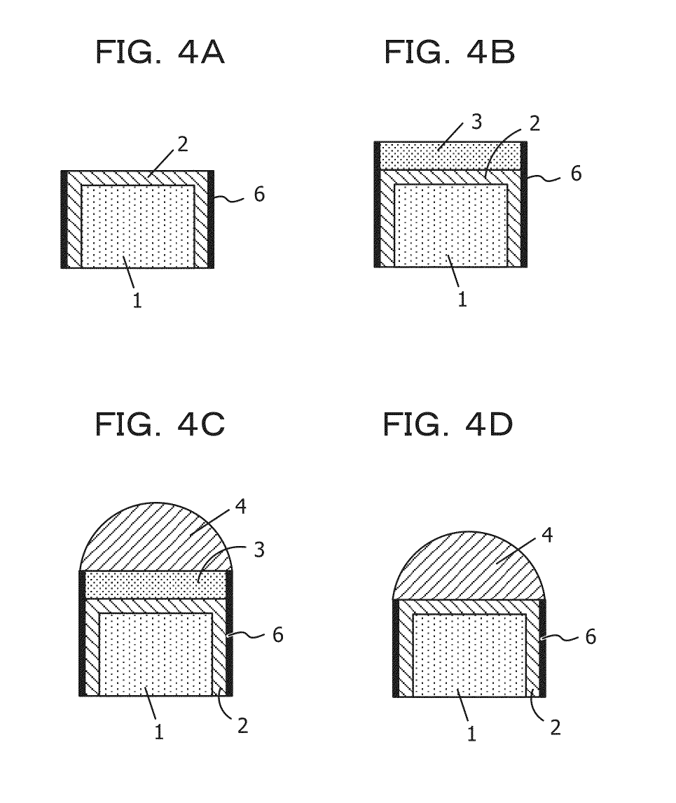

The cover layer 2 may be provided with a bonding layer 3 thereon containing a metal material capable of being solder-bonded, as illustrated in FIGS. 1, 2B, 3, 4B and 4C. More specifically, the bonding layer 3 is preferably formed on the portion of the cover layer 2 covering the upper surface of the pillar 1. Preferably, the solder layer 4 is disposed on the bonding layer 3, as illustrated in FIGS. 1 and 4C. If the bonding layer 3 containing a metal material capable of being solder-bonded is formed, the composition of the alloy of the metal material and the solder material produced by solder bonding may be controlled by controlling the thickness of the bonding layer 3.

If the bonding layer 3 is provided, the portion of the cover layer 2 covering the upper surface of the pillar 1 is located between the pillar 1 and the bonding layer 3. Hence, the terminal is has a multilayer structure including, for example, the cover layer 2, the bonding layer 3 and the solder layer 4 in that order on the pillar 1. The portion of the cover layer 2 covering the upper surface of the pillar 1 is therefore located within the terminal. In this instance, the cover layer 2 is disposed, in part, within the terminal, but covers, in part, the side surface of the terminal.

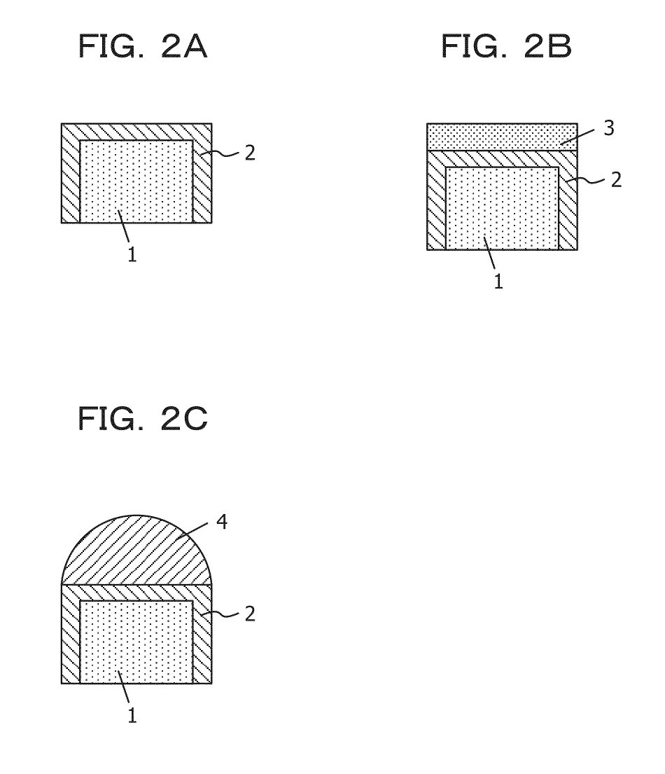

The cover layer 2 is not limited to this form and may contain Ni as the second metal material. In this instance, the solder layer 4 may be disposed directly on the cover layer 2 without forming the bonding layer 3, as illustrated in FIGS. 2C and 4D. In this instance, the metal material of the cover layer 2, that is, Ti, Cr, Ta, Al, W or Mo, or an alloy containing any of these metals, allows the solder material to diffuse more slowly (at a lower diffusion rate) thereinto than into Ni. Therefore the use of Ti, Cr, Ta, Al, W or Mo, or an alloy containing any of these metals in the cover layer 2 hinders the solder material from diffusing into the side surface of the pillar 1.

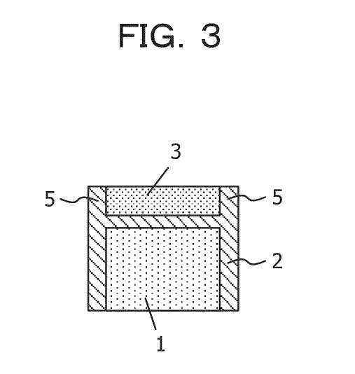

If the bonding layer 3 is provided, another cover layer 5 may be provided for the side surface of the bonding layer 3, as illustrated in FIG. 3. An oxide film (passive film) 6 may be formed over the surface of the portion of the cover layer 2 covering the side surface of the pillar 1, as illustrated in FIGS. 4A to 4D. The oxide film 6 may be a metal oxide film formed over the surface of the portion of the cover layer 2 covering the side surface of the pillar 1 by oxidizing the metal material of the cover layer 2. If a bonding layer 3 is disposed on the cover layer 2 as illustrated in FIGS. 4B and 4C, the oxide film 6 may cover also the side surface of the bonding layer 3.

The oxide film 6, in this instance, may include a metal oxide film formed over the surface of the portion of the cover layer 2 covering the side surface of the pillar 1 by oxidizing the metal material of the cover layer 2, and a metal oxide film formed over the side surface of the bonding layer 3 by oxidizing the metal material of the bonding layer 3. It is advantageous to cover the surface (metal surface) of the terminal that will come in contact with the ambient air with the oxide film 6. The solder material thus may be kept from diffusing into the side surface of the pillar 1 with reliability. In addition, the wettability of solder is reduced on the surface of the oxide film 6. Accordingly, when solder is melted for solder bonding, the solder may be kept from flowing over the side surface.

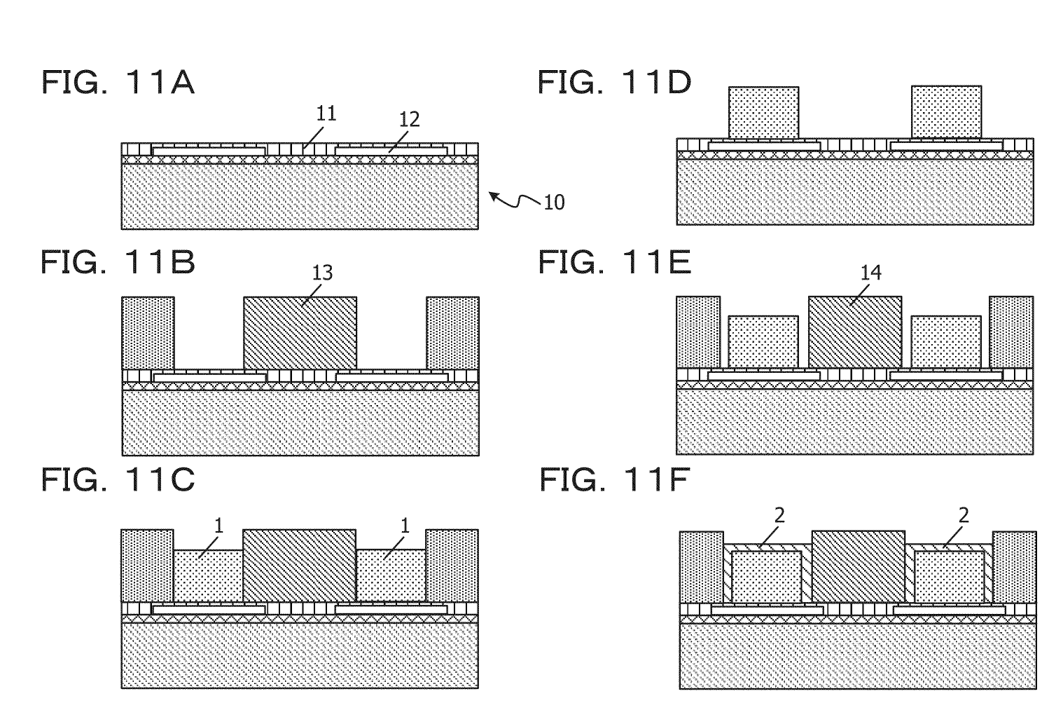

The terminal having the above-described structure may be formed as below. A terminal forming method according to an embodiment includes forming the pillar 1 containing the first metal material, and forming the cover layer 2 containing the second metal material into which solder material will diffuse more slowly than into the first metal material so as to cover the upper and side surfaces of the pillar 1 (see FIGS. 11A to 12E and FIGS. 15A to 20G).

The pillar 1 preferably contains Cu as the first metal material, and the solder material preferably contains Sn. If the terminal structure includes a solder layer 4 (see FIGS. 1, 2C, 4C, and 4D), the method further includes forming the solder layer 4 right above the cover layer 2.

If the cover layer 2 contains a metal selected from the group consisting of Ti, Cr, Ta, Al, W and Mo as the second metal material, preferably, the terminal forming method further includes forming a bonding layer 3 containing a metal material capable of being soldered on the cover layer 2 (see FIGS. 1, 2B, 3, 4B, and 4C). In this instance, the solder layer 4 is preferably formed on the bonding layer 3 in the operation of forming the solder layer 4 (see FIGS. 1 and 4C).

If the cover layer 2 contains Ni as the second metal material, the solder layer 4 may be formed on the cover layer 2 (see FIGS. 2C and 4D) in the operation of forming the solder layer 4. In other words, the terminal forming method may include forming the solder layer 4 without including forming the bonding layer 3. If the terminal structure includes an oxide film 6 (see FIGS. 4A to 4D), the terminal forming method further includes forming the oxide film 6 so as to cover the surface of the portion of the cover layer 2 covering the side surface of the pillar 1. For example, the operation of forming the oxide film 6 may be performed after the formation of the cover layer 2 as the operation of forming a metal oxide film 6 on the surface of the portion of the cover layer 2 covering the side surface of the pillar 1 by oxidizing the metal material of the cover layer 2. This operation of forming the metal oxide film 6 may be performed by, for example, heating the cover layer 2 so as to oxidize in an air atmosphere the metal material of the cover layer 2 at the surface (external surface) thereof covering the pillar 1.

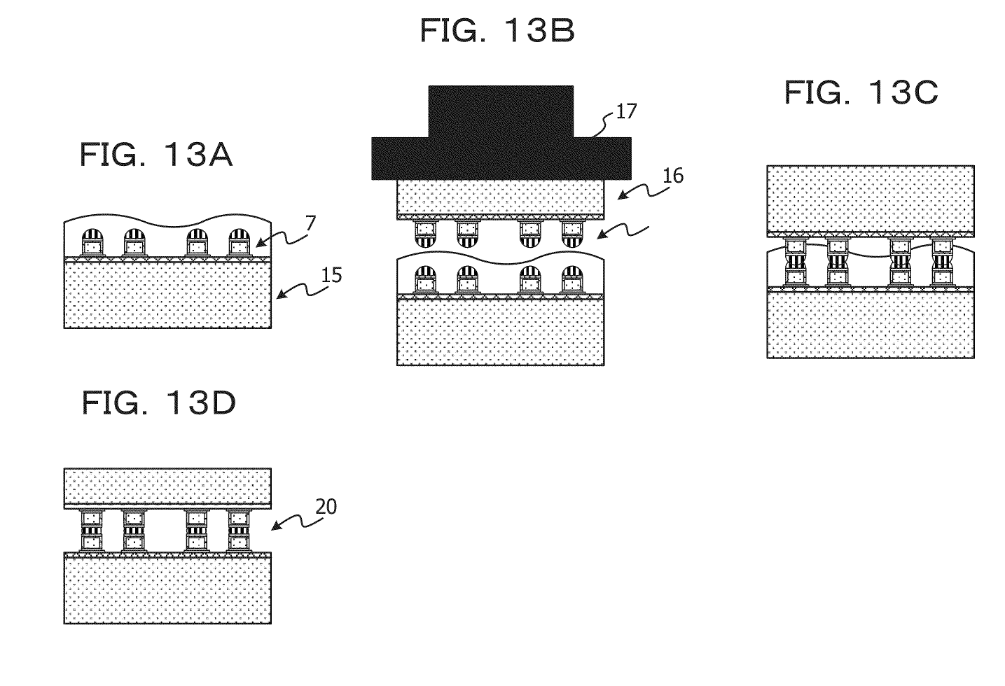

A semiconductor device according to an embodiment is a semiconductor component 20 (see FIG. 13D) in which semiconductor chips or a semiconductor chip and a substrate are electrically connected with the terminals having the above-described structure. The semiconductor component may be referred to as semiconductor package. Hence, the semiconductor device is a semiconductor component in which semiconductor chips including the terminals having the above-described structure or a semiconductor chip including the terminals having the above-described structure and a substrate including the terminals having the above-described structure are solder-bonded to each other to be electrically connected to each other.

As described above, the semiconductor device is a semiconductor component including a first semiconductor chip and a second semiconductor chip or a substrate that are electrically connected to each other. The first semiconductor chip includes a first terminal including a first pillar 1 containing a first metal material, and a first cover layer covering the upper and side surfaces of the first pillar and containing a second metal material into which solder material will diffuse more slowly than into the first metal material. The second semiconductor chip or the substrate includes a second terminal including a second pillar containing a third metal material, and a second cover layer covering the upper and side surfaces of the second pillar and containing a fourth metal material into which the solder material will diffuse more slowly than into the third metal material. The electrical connection between the first semiconductor chip and the second semiconductor chip or the substrate is established by solder bonding with a solder layer disposed between the first cover layer and the second cover layer.

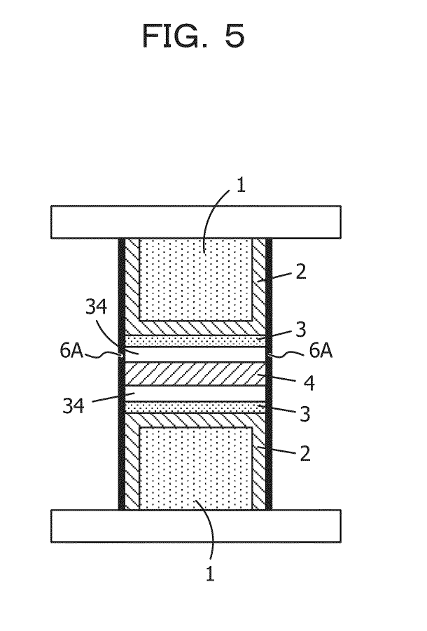

If the terminal structure does not include the oxide film 6, an oxide film 6A may be formed, after the terminals have been solder-bonded in the process for producing the semiconductor component, over the entirety of the side surfaces of the solder-bonded terminals, that is, the side surfaces of the two terminals and the side surfaces of the solder layers (and a layer of a compound of the solder and the metal material), for example, as illustrated in FIG. 5. For example, the metal oxide film 6A may be formed, after the terminals have been solder-bonded in the process for producing the semiconductor component, in such a manner that the metal material in the outermost portions of the side surfaces of the solder-bonded terminals is oxidized by being heated in an air atmosphere.

The solder material thus may be kept from diffusing into the side surface of the pillar 1. In FIG. 5, reference numeral 34 denotes a compound of the metal material of the bonding layer 3 and the solder material. Although FIG. 5 illustrates an example in which the metal oxide film 6A is provided for the terminal structure including the bonding layer 3, the metal oxide film 6A may be provided for any of the terminal structures as illustrated in FIGS. 1 to 3. In such a case, if the bonding layer 3 is not formed, a layer of a compound of the metal material, such as Ni, of the cover layer 2 and the solder material will be produced between the cover layer 2 and the solder layer 4.

An electronic apparatus according to an embodiment includes such a semiconductor component 20 (semiconductor device), as illustrated in FIGS. 14A to 14G. For example, the electronic apparatus may be a server 24 (server system) including the semiconductor component 20. The server may be built as below. First, a semiconductor component 20 including semiconductor chips electrically connected to each other is produced by solder-bonding terminals having the above-described structure, as illustrated in FIG. 14A. Then, the semiconductor component 20 is mounted on a substrate 21, such as a package substrate, as illustrated in FIG. 14B, and is electrically connected to the substrate 21 by wire bonding, as illustrated in FIG. 14C.

Subsequently, the resulting structure is encapsulated in resin as illustrated in FIG. 14D. Thus, an electronic component 22 is completed as illustrated in FIG. 14E. Then, the electronic component 22 is mounted on a system board 23, as illustrated in FIG. 14F, followed by being accommodated in an enclosure. Thus, a server 24 including the semiconductor component 20 is built as illustrated in FIG. 14G. The server 24 is used, for example, for a highly reliable intelligent transport system in which the server 24 analyzes a large amount of information collected from mobiles (vehicles in the case of FIG. 14) for accurate instruction, transport control and the like.

The terminal structure, the semiconductor device, the electronic apparatus and the terminal forming method of the above-described embodiments are advantageous for keeping solder material from diffusing into the side surface of the pillar 1 containing a metal material and increasing the reliability of bonding. An exemplary embodiment will now be described in which the terminal is formed right above an electrode pad on a circuit of a semiconductor element.

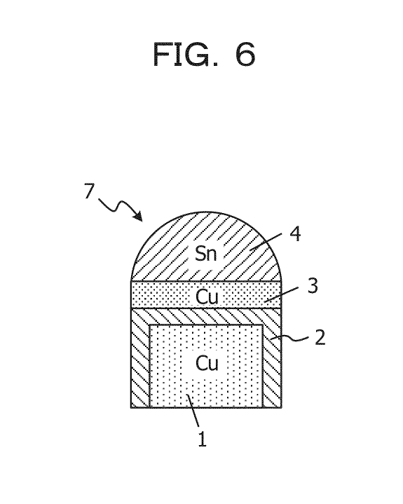

As illustrated in FIG. 6, this terminal includes a Cu pillar 1, a cover layer 2 covering the upper and side surfaces of the Cu pillar 1 and containing Ti, Cr, Ta, Al, W or Mo, into which Sn will diffuse more slowly than into Cu, a Cu bonding layer 3 on the cover layer 2, and a solder layer 4 containing Sn on the Cu bonding layer 3. In other words, the semiconductor element includes a terminal 7 including a Cu pillar 1, a cover layer 2 covering the upper and side surfaces of the Cu pillar 1 and containing Ti, Cr, Ta, Al, W or Mo, into which Sn will diffuse more slowly than into Cu, a Cu bonding layer 3 on the cover layer 2, and a solder layer 4 containing Sn on the Cu bonding layer 3.

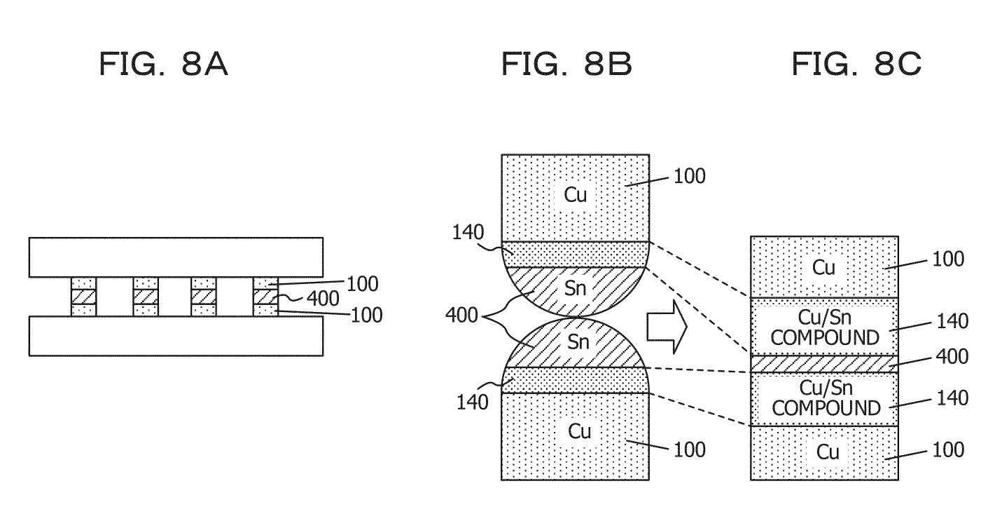

This structure keeps the Sn from diffusing into the side surface of the Cu pillar 1 of the solder-bonded terminal, thus enhancing the reliability of bonding, as illustrated in FIG. 7. In FIG. 7, reference numeral 34 denotes a compound (CuSn compound) of Cu, which is the metal material of the bonding layer 3, and Sn, which is the solder material. If Cu pillars (Cu pillar bumps) 100 are used instead of solder bumps for flip-chip bonding of semiconductor chips or a semiconductor chip and a substrate in such a manner that the Cu pillars 100 opposed to each other are bonded with a solder material 400 containing Sn, as illustrated in FIGS. 8A to 8C, the Sn diffuses into the Cu pillars 100. Thus, a large amount of compound of Cu and Sn (Cu/Sn compound) 140 is produced. This may reduce, for example, bonding strength and thus degrade the reliability of bonding. For the sake of simplicity, FIG. 8A omits the Cu/Sn compound 140.

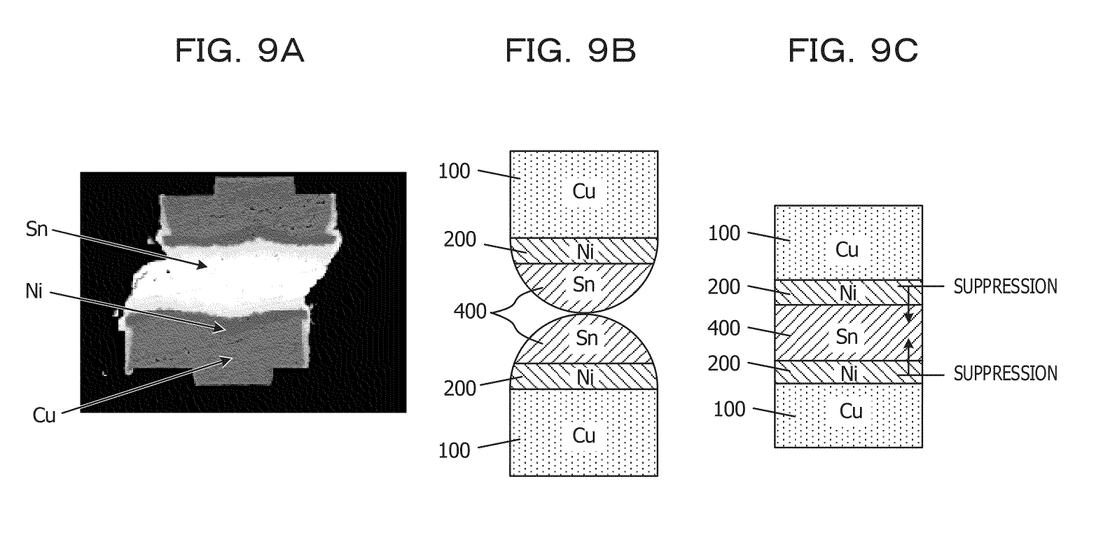

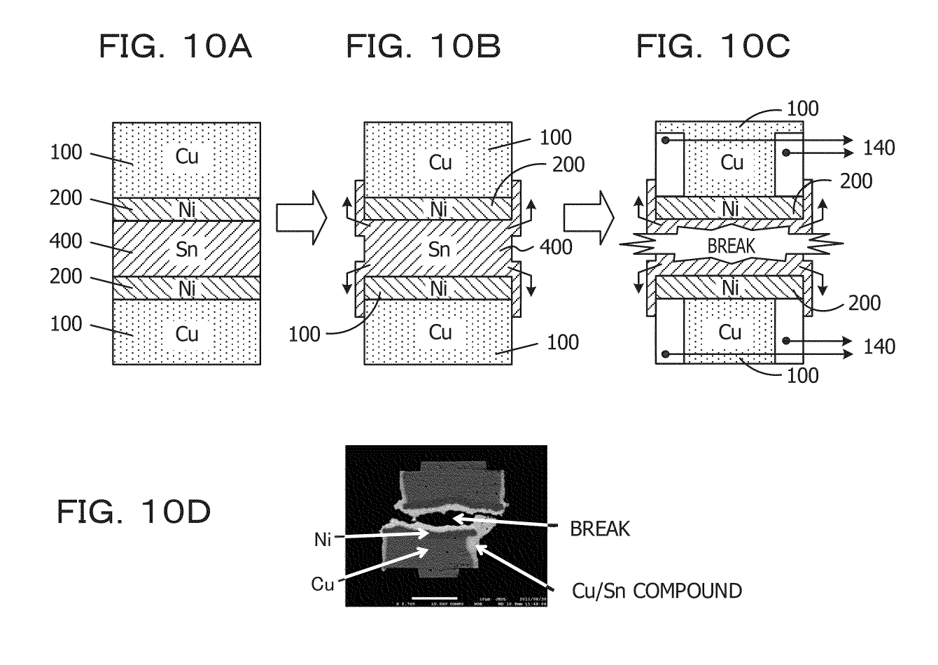

It may be effective in suppressing this diffusion to provide the Cu pillar 100 with a Ni layer 200 as a barrier metal layer on the top thereof, that is, between the Cu pillar 100 and the solder layer 400 containing Sn, as illustrated in FIGS. 9A to 9C. Since Sn diffuses into Ni more slowly than into Cu, the Ni layer 200 is expected to keep the Sn from diffusing into Cu. It has been found, however, that if the terminals receive a thermal load after being solder-bonded, for example, for high temperature storage test, the Sn migrates (diffuses) to the side surfaces of the Cu pillars 100 along the surfaces of the Ni layers 200 due to solid-phase diffusion at the surfaces and thereby decreases in amount in the bonded portion, as illustrated in FIGS. 10A to 10D. This may result in bonding failure such as a break in the bonded portion and thus reduce the reliability of bonding. In this instance, a Cu/Sn compound 140 is produced on the side surfaces of the Cu pillars 100.

Accordingly, in the present embodiment, the cover layer 2 containing Ti, Cr, Ta, Al, W or Mo, into which Sn diffuses more slowly than into Cu, covers not only the upper surface of the Cu pillar 1, but also the side surface of the Cu pillar 1, as described above (see FIG. 6). Thus the Sn may be kept from diffusing into (flowing to) the side surfaces of the Cu pillars 1 after the terminals are solder-bonded, thus reducing the occurrence of bonding failure such as a break in the bonded portion to increase reliability of bonding (see FIG. 7).

If the Cu bonding layer 3 is formed between the cover layer 2 and the solder layer 4 containing Sn, as described above, the composition of the Cu—Sn alloy produced by solder bonding may be controlled by controlling the thickness of the Cu bonding layer 3. The terminal 7 having this structure may be formed by the following method. This method is referred to as a first terminal forming method.

First, as illustrated in FIG. 11A, a plating seed layer 11 is formed over the surface of the circuit of a semiconductor element. In the present embodiment, a plating seed layer 11 of Ti/Cu (100 nm/500 nm) is formed over the surface of the circuit of a semiconductor wafer 10 by sputtering. Next, as illustrated in FIG. 11B, a resist mask 13 is formed which has openings in the regions thereof right above the electrode pads 12 on the surface of the circuit of the semiconductor element, where Cu pillars 1 will be formed. In the present embodiment, the resist mask 13 having openings in the regions thereof where Cu pillars 1 will be formed is formed by photolithography using a resist layer, that is, by exposing and developing the regions right above the electrode pads 12 on the surface of the circuit of the semiconductor element, where the Cu pillars 1 will be formed.

Next, as illustrated in FIG. 11C, Cu pillars 1 are formed on the plating seed layer 11 covering the electrode pads 12 on the surface of the circuit of the semiconductor element, using the resist mask 13. In the present embodiment, Cu is grown in a columnar shape on the plating shield layer 11 by electrolytic plating using the resist mask 13 having the openings in the regions where the Cu pillars 1 will be formed, thus forming the Cu pillars 1.

Then, after the resist mask 13 is removed as illustrated in FIG. 11D, another resist mask 14 is formed which has openings in the regions including the Cu pillars 1 and spaces at the sides of the Cu pillars 1 for forming cover layers 2, as illustrated in FIG. 11E. In the present embodiment, the resist mask 14 having openings in the regions including spaces at the sides of the Cu pillars 1 for forming cover layers 2 is formed by photolithography using a resist layer, that is, by exposing and developing regions each including the Cu pillar 1 and having a larger area than the Cu pillar 1.

Next, as illustrated in FIG. 11F, cover layers 2 are formed so as to cover the upper and side surfaces of the Cu pillars 1 using the resist mask 14. In the present embodiment, Cr is grown on the plating shield layer 11 and the upper and side surfaces of the Cu pillars 1 by electrolytic plating using the resist mask 14 having openings in the regions including the spaces at the sides of the Cu pillars 1 for forming the cover layers 2, thus forming Cr cover layers 2. Although the present embodiment uses Cr for forming the cover layers 2, the cover layers 2 may be formed of, for example, Ti, Ta, Al, W or Mo without being limited to Cr.

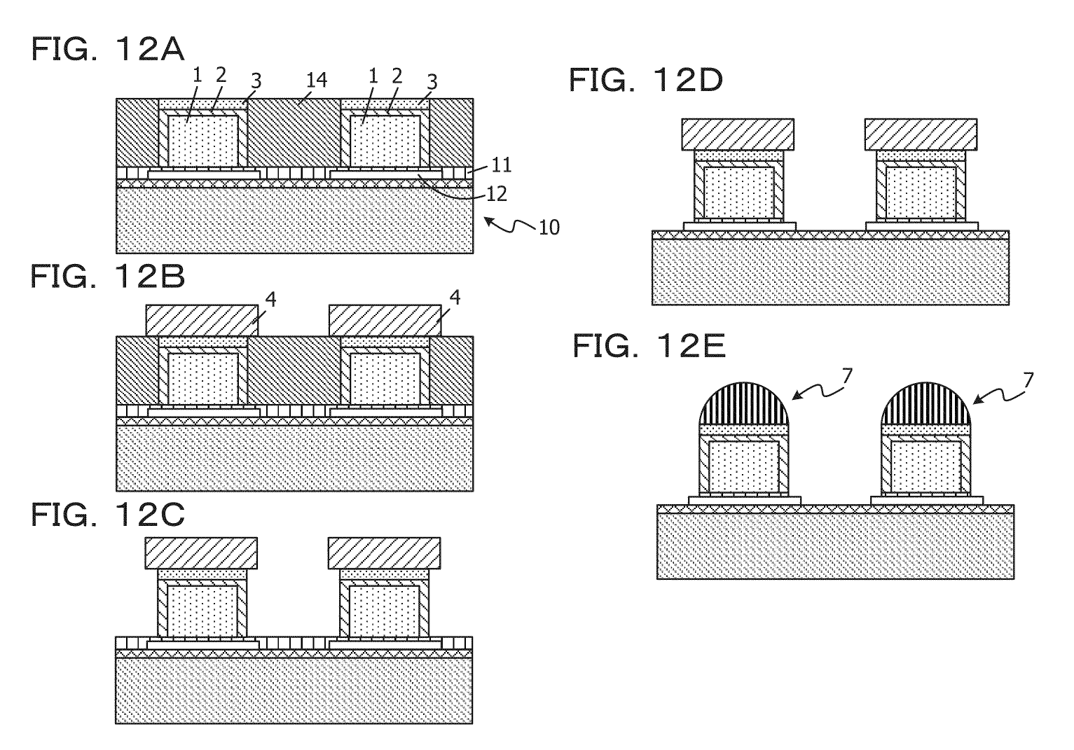

Next, as illustrated in FIG. 12A, bonding layers 3 are formed on the cover layers 2, using the resist mask 14. In the present embodiment, Cu is grown on the upper surfaces of the Cr cover layers 2 by electrolytic plating using the resist mask 14, thus forming Cu bonding layers (Cu plating layers) 3. Then, as illustrated in FIG. 12B, solder layers 4 are formed on the bonding layers 3. In the present embodiment, SnAg solder is grown on the upper surfaces of the Cu bonding layers 3 by electrolytic plating, thus forming SnAg solder layers (SnAg solder plating layers) 4.

Then, after the resist mask is removed as illustrated in FIG. 12C, unnecessary portions of the plating seed layer 11 are removed by etching, as illustrated in FIG. 12D. Finally, as illustrated in FIG. 12E, the solder layers 4, which are plating layers, are melted and solidified to be formed into a stable shape by reflow. In the present embodiment, the SnAg solder layers 4, which are plating layers, are melted and solidified to be formed into a stable shape by a reflowing wet back operation.

If the terminal structure includes an oxide film 6 (see FIGS. 4A to 4D), the oxide films 6 are formed so as to cover the surfaces of the portions of the cover layers 2 covering the side surfaces of the pillars 1, as described above, after the cover layers 2 have been formed, for example, after the terminals 7 have been formed. For this operation, for example, a metal oxide film may be formed over the surfaces of the portions of the cover layers 2 covering the pillars 1 by heating the cover layers 2 at a temperature of about 150° C. to about 200° C. in an air furnace so as to oxidize the metal material of the cover layers 2.

Thus, the terminals 7 having the above-described structure are formed right above the electrode pads 12 on the surface of the circuit of a semiconductor element, as illustrated in FIG. 12E. In the present embodiment, a semiconductor wafer 10 is produced which includes the terminals 7 formed right above the electrode pads 12 on the surface of the circuit thereof as described above. Then, the semiconductor wafer 10 including the terminals 7 having the above-described structure is divided into semiconductor chips 15 and 16 each including the terminals 7 having the above-described structure (see FIGS. 13A and 13B).

For example, for producing a semiconductor component 20 including semiconductor chips electrically connected to each other (see FIG. 13D), the semiconductor chips 15 and 16 each including the terminals 7 having the above-described structure are produced as the semiconductor chips to be bonded (see FIGS. 13A and 13B), and the terminals 7 are solder-bonded to each other (see FIGS. 13C and 13D). Such a semiconductor component 20 may be referred to as bonded body.

Although the present embodiment illustrates the process in which the terminals 7 having the above-described structure are formed on the surface of a semiconductor wafer 10 or semiconductor elements such as the semiconductor chips 15 and 16, the same process may be used for forming the terminals on the surface of a substrate, such as a circuit board, a wiring board, a package substrate, or a build-up board. For example, for producing a semiconductor component including a semiconductor chip and a substrate that are electrically connected to each other, a semiconductor chip and a substrate, each including terminals having the above-described structure are produced as the semiconductor chip and substrate to be bonded, and the terminals are solder-bonded to each other.

The semiconductor components 20 including the semiconductor chips electrically connected to each other may be produced, for example, as below. First, after a flux (such as rosin flux) 17 is applied to the lower semiconductor chip 15, as illustrated in FIG. 13A, the upper semiconductor chip 16 is temporally mounted on the lower semiconductor chip 15 at room temperature with the terminals 7 of the lower and upper semiconductor chips 15 and 16 aligned using a flip-chip bonder 17, as illustrated in FIG. 13B. Then, the semiconductor chips are subjected to reflow for solder-bonding the terminals having the above-described structure, as illustrated in FIG. 13C, by heating at about 220° C. or more (up to a peak temperature of about 260° C.) for about 60 seconds in a nitrogen atmosphere in a reflow furnace. Then, the flux is washed away to yield a semiconductor component 20 including the lower and upper semiconductor chips electrically connected to each other.

If the terminal structure does not include the oxide film 6, an oxide film 6A may be formed over the side surfaces of the solder-bonded terminals after the terminals have been solder-bonded in the process for producing the semiconductor component 20 (see FIG. 5). For example, the metal oxide film 6A may be formed, after the terminals have been solder-bonded in the process for manufacturing the semiconductor component 20, in such a manner that the metal material in the outermost portions of the side surfaces of the solder-bonded terminals is oxidized by being heated at a temperature of about 150° C. to about 200° C. in an air furnace.

Thus produced semiconductor components 20 were subjected to high temperature storage test in a thermostatic oven of about 150° C., and the bonding of the terminals 7 was evaluated by checking electrical continuity. The results are as below. For comparison, a semiconductor component produced by solder-bonding known Cu pillar bumps (see FIGS. 8A to 8C) was also subjected to the same test and evaluation.

For the semiconductor component produced by solder-bonding the known Cu pillar bumps (see FIGS. 8A to C), nine of ten samples had faulty electrical continuity after about 1000 hours and resulted in connection failure. For the semiconductor component 20 of the present embodiment produced by solder-bonding the terminals 7 having the above-described structure, on the other hand, it was confirmed that ten of ten samples had electrical continuity even after the storage test and thus exhibited improved reliability of bonding.

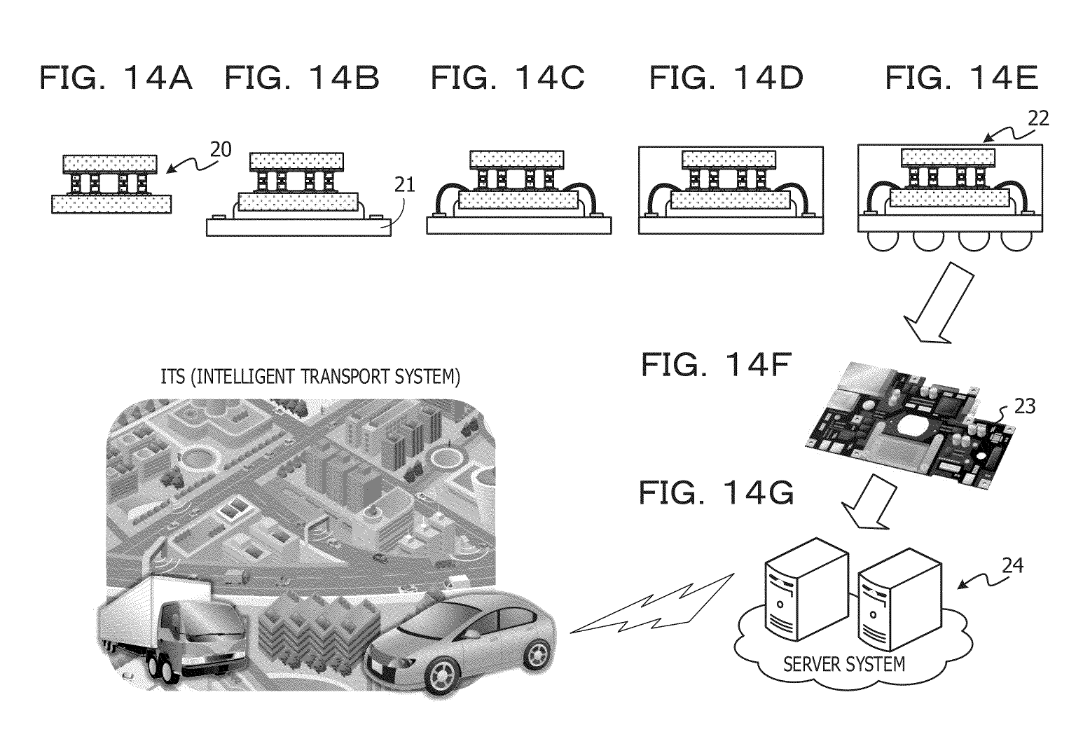

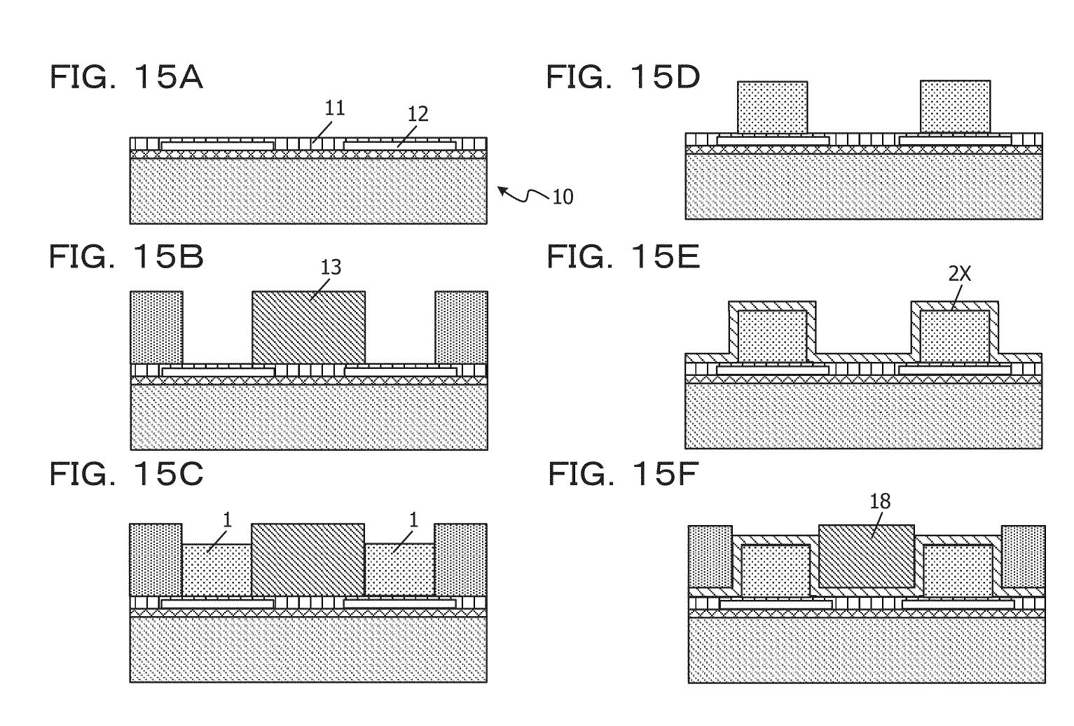

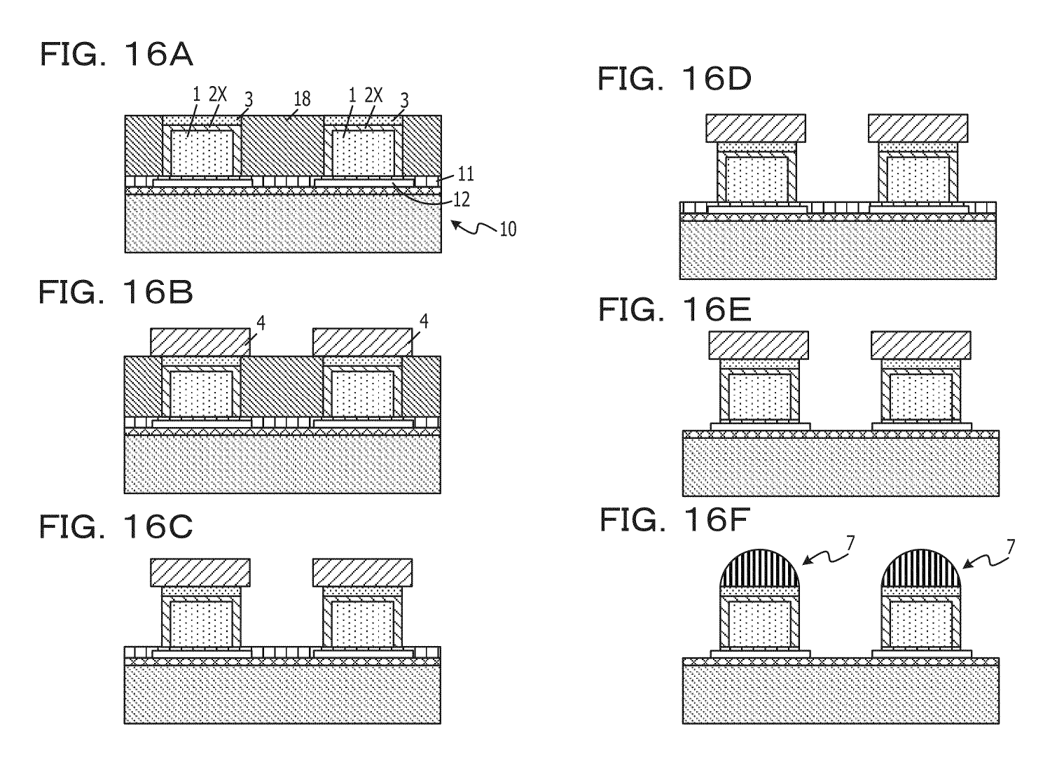

The method for forming the terminal 7 having the above-described structure is not limited to the first terminal forming method, and the following second to fourth terminal forming methods may be applied to the process for forming the terminal 7 having the above-described structure. The second terminal forming method will first be described with reference to FIGS. 15A to 16F. In the second terminal forming method, first, a plating seed layer 11 is formed as illustrated in FIG. 15A. Then, a resist mask 13 is formed as illustrated in FIG. 15B, and Cu pillars 1 are formed as illustrated in FIG. 15C. These operations are performed in the same manner as in the first terminal forming method.

Then, after the resist mask is removed as illustrated in FIG. 15D, a Ti layer (Ti film) 2X that will be formed into the cover layers 2 is formed over the entireties of the upper and side surfaces of the Cu pillars 1 by sputtering, as illustrated in FIG. 15E. Subsequently, a resist mask 18 is formed which has openings in the regions including the Cu pillars 1 and the portions of the Ti layer 2X on the upper and side surfaces of the Cu pillars 1, as illustrated in FIG. 15F. In the present embodiment, the resist mask 18 having openings in the regions including the Cu pillars 1 and the portions of the Ti layer 2X on the upper and side surfaces of the Cu pillars 1 is formed by photolithography using a resist layer, that is, by exposing and developing the regions including the Cu pillars 1 and the portions of the Ti layer 2X on the upper an side surfaces of the Cu pillars

Next, as illustrated in FIG. 16A, bonding layers 3 are formed on the Ti layer 2X that will be formed into the cover layers 2, using the resist mask 18. In the present embodiment, Cu is grown on the upper surfaces of the Ti layer 2X by electrolytic plating using the resist mask 18, thus forming Cu bonding layers (Cu plating layers) 3. Then, as illustrated in FIG. 16B, solder layers 4 are formed on the bonding layers 3. In the present embodiment, SnAg solder is grown on the upper surfaces of the Cu bonding layers 3 by electrolytic plating, thus forming SnAg solder layers (SnAg solder plating layers) 4.

Then, after the resist mask is removed as illustrated in FIG. 16C, unnecessary portions of the Ti layer 2X are removed by etching (for example, dry etching), as illustrated in FIG. 16D. Thus, the remaining portions of the Ti layer 2X are defined as the cover layers 2 covering the upper and surfaces of the Cu pillars 1. Hence, the Ti cover layers 2 are formed on the plating seed layer 11 and the upper and side surfaces of the Cu pillars 1. Although the present embodiment uses Ti for forming the cover layers 2, the cover layers 2 may be formed of, for example, Cr, Ta, Al, W or Mo without being limited to Ti.

Subsequently, unnecessary portions of the plating seed layer 11 are removed as illustrated in FIG. 16E by etching, as in the first terminal forming method. Finally, as illustrated in FIG. 16F, the solder layers 4, which are plating layers, are melted and solidified to be formed into a stable shape by reflow, as in the first terminal forming method. Thus, the terminals 7 having the above-described structure are formed right above the electrode pads 12 on the surface of the circuit of a semiconductor element.

In the present embodiment, a semiconductor wafer 10 is produced which includes the terminals 7 formed right above the electrode pads 12 on the surface of the circuit thereof as described above. Then, the semiconductor wafer 10 including the terminals 7 having the above-described structure is divided into semiconductor chips 15 and 16 each including the terminals 7 having the above-described structure (see FIGS. 13A and 13B), as in the case of forming the terminals 7 having the above-described structure by the first terminal forming method.

Also, a semiconductor component 20 including the semiconductor chips electrically connected to each other (see FIG. 13D) may be produced as in the case of forming the terminals 7 having the above-described structure by the first terminal forming method. Thus produced semiconductor components 20 were subjected to high temperature storage test in a thermostatic oven of about 150° C. for evaluating the bonding of the terminals. As a result, it was confirmed that ten of ten samples had electrical continuity even after the storage test and thus exhibited improved reliability of bonding.

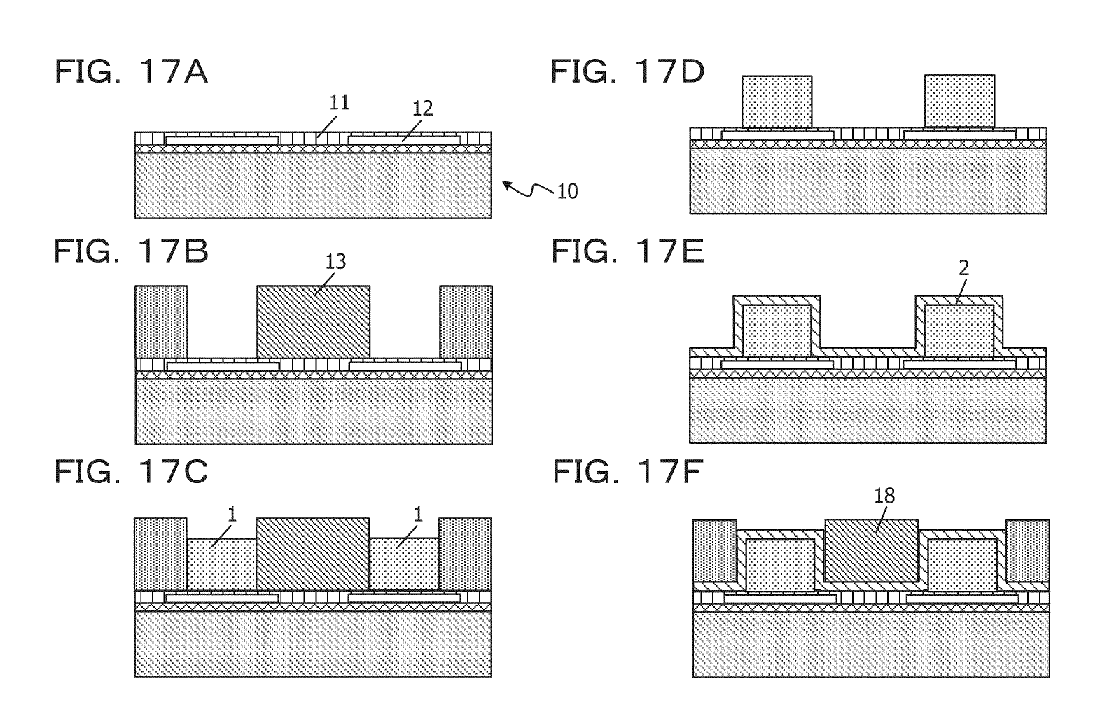

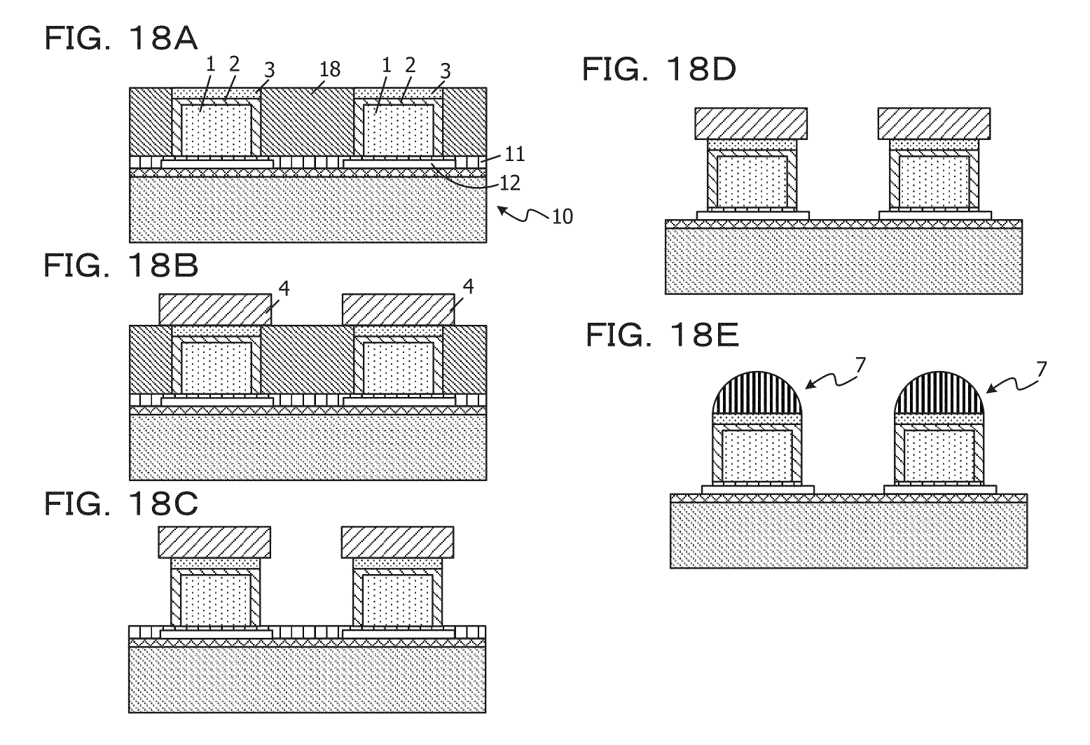

The third terminal forming method will now be described with reference to FIGS. 17A to 18E. In the third terminal forming method, first, a plating seed layer 11 is formed as illustrated in FIG. 17A. Then, a resist mask 13 is formed as illustrated in FIG. 17B, and Cu pillars 1 are formed as illustrated in FIG. 17C. These operations are performed in the same manner as in the first terminal forming method. Next, after the resist mask is removed as illustrated in FIG. 17D, cover layers 2 are formed so as to cover the upper and side surfaces of the Cu pillars 1, as illustrated in FIG. 17E. In the present embodiment, W is grown on the plating seed layer 11 and the upper and side surfaces of the Cu pillars 1 by selective chemical vapor deposition (CVD), thus forming W cover layers 2. Although the present embodiment uses W for forming the cover layers 2, the cover layers 2 may be formed of, for example, Cr, Ti, Ta, Al or Mo without being limited to W.

Then, another resist mask 18 is formed which has openings in the regions including the Cu pillars 1 and the W cover layers 2 on the upper and side surfaces of the Cu pillars 1, as illustrated in FIG. 17F. In the present embodiment, the resist mask 18 having openings in the regions including the Cu pillars 1 and the W cover layers 2 on the upper and side surfaces of the Cu pillars 1 is formed by photolithography using a resist layer, that is, by exposing and developing the regions including the Cu pillars 1 and the W cover layers 2 on the upper and side surfaces of the Cu pillars 1.

Then, bonding layers 3 are formed as illustrated in FIG. 18A, and solder layers 4 are formed as illustrated in FIG. 18B. After the resist mask is removed as illustrated in FIG. 18C and unnecessary portions of the plating seed layer 11 are removed as illustrated in FIG. 18D, the solder layers 4, which are plating layers, are formed into a stable shape as illustrated in FIG. 18E. These operations are performed in the same manner as in the first terminal forming method. Thus, the terminals 7 having the above-described structure are formed right above the electrode pads 12 on the surface of the circuit of a semiconductor element.

In the present embodiment, a semiconductor wafer 10 is produced which includes the terminals 7 formed right above the electrode pads 12 on the surface of the circuit thereof as described above. Then, the semiconductor wafer 10 including the terminals 7 having the above-described structure is divided into semiconductor chips 15 and 16 each including the terminals 7 having the above-described structure (see FIGS. 13A and 13B), as in the case of forming the terminals 7 having the above-described structure by the first terminal forming method.

Also, a semiconductor component 20 including the semiconductor chips electrically connected to each other (see FIG. 13D) may be produced as in the case of forming the terminals 7 having the above-described structure by the first terminal forming method. Thus produced semiconductor components 20 were subjected to high temperature storage test in a thermostatic oven of about 150° C. for evaluating the bonding of the terminals. As a result, it was confirmed that ten of ten samples had electrical continuity even after the storage test and thus exhibited improved reliability of bonding.

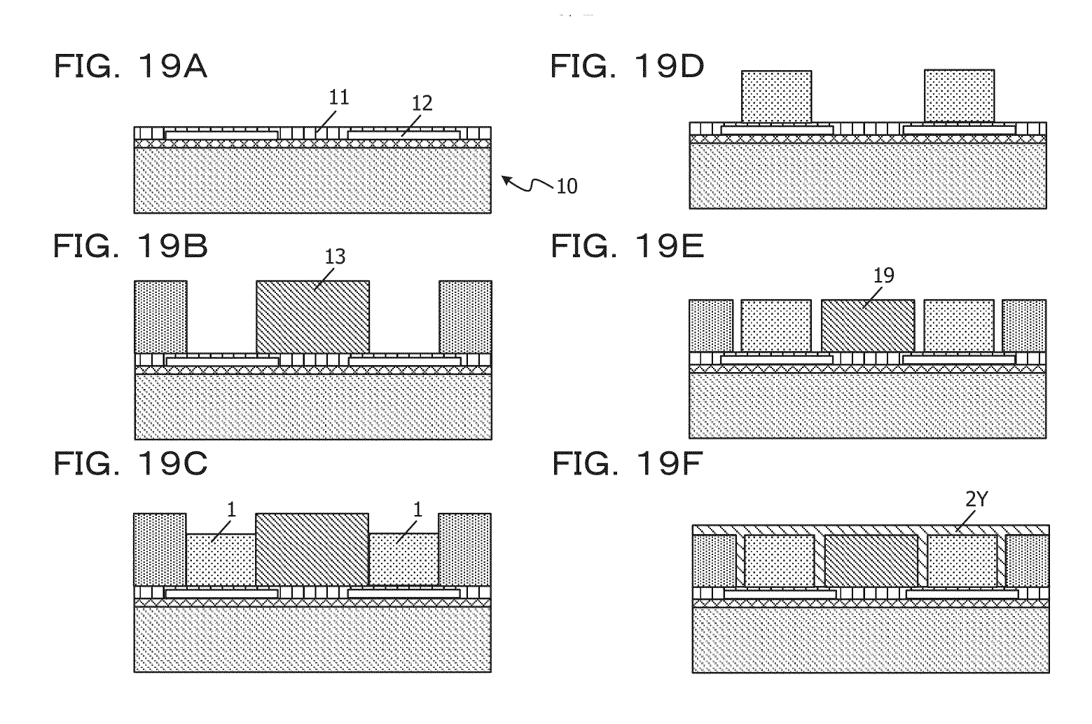

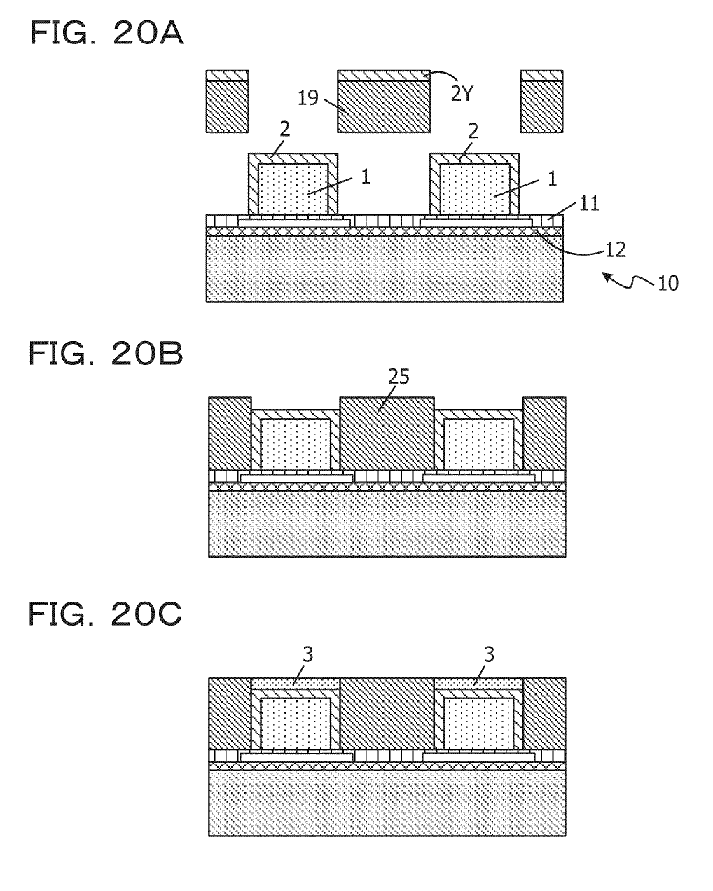

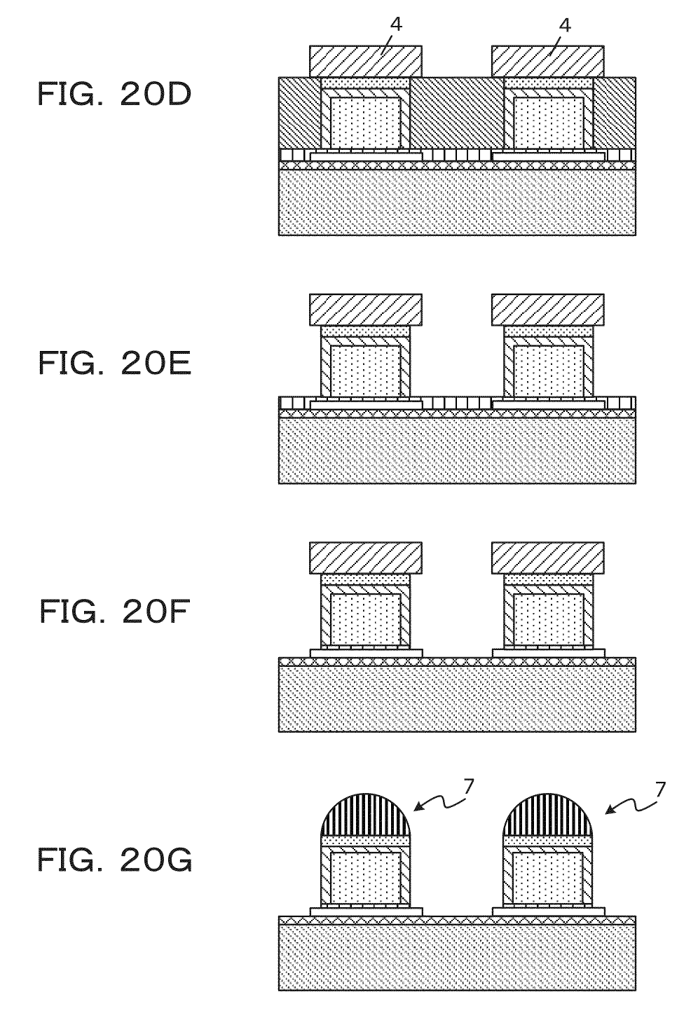

The fourth terminal forming method will now be described with reference to FIGS. 19A to 20G. In the fourth terminal forming method, first, a plating seed layer 11 is formed as illustrated in FIG. 19A, and a resist mask 13 is formed as illustrated in FIG. 19B. Then, Cu pillars 1 are formed as illustrated in FIG. 19C, and the resist mask is removed as illustrated in FIG. 19D. These operations are performed in the same manner as in the first terminal forming method.

Then, another resist mask 19 is formed which has openings in the regions including the Cu pillars 1 and spaces at the sides of the Cu pillars 1 for forming cover layers 2, as illustrated in FIG. 19E. In the present embodiment, the resist mask 19 having openings in the regions including spaces at the sides of the Cu pillars 1 for forming cover layers 2 is formed by photolithography using a resist layer, that is, by exposing and developing regions including the Cu pillars 1 and having a larger area than the Cu pillars 1.

Subsequently, a Ti layer (Ti film) 2Y that will be formed into the cover layers 2 covering the upper and side surfaces of the Cu pillars 1 is formed over the entire surface, as illustrated in FIG. 19F, by sputtering, and then the resist mask is removed by a lift-off process, as illustrated in FIG. 20A. Thus, unnecessary portions of the Ti layer 2Y are removed to yield Ti cover layers 2 on the plating seed layer 11 and the upper and side surfaces of the Cu pillars 1. The cover layers 2 covering the upper and surfaces of the Cu pillars 1 are thus formed. Although the present embodiment uses Ti for forming the cover layers 2, the cover layers 2 may be formed of, for example, Cr, Ta, Al, W or Mo without being limited to Ti.

Then, another resist mask 25 is formed which has openings in the regions including the Cu pillars 1 and the Ti cover layers 2 on the upper and side surfaces of the Cu pillars 1, as illustrated in FIG. 20B. In the present embodiment, the resist mask 25 having openings in the regions including the Cu pillars 1 and the Ti cover layers 2 on the upper and side surfaces of the Cu pillars 1 is formed by photolithography using a resist layer, that is, by exposing and developing the regions including the Cu pillars 1 and the Ti cover layers 2 on the upper and side surfaces of the Cu pillars 1.

Then, bonding layers 3 are formed as illustrated in FIG. 20C, and solder layers 4 are formed as illustrated in FIG. 20D. After the resist mask is removed as illustrated in FIG. 20E and unnecessary portions of the plating seed layer 11 are removed as illustrated in FIG. 20F, the solder layers 4, which are plating layers, are formed into a stable shape as illustrated in FIG. 20G. These operations are performed in the same manner as in the first terminal forming method. Thus, the terminals 7 having the above-described structure are formed right above the electrode pads 12 on the surface of the circuit of a semiconductor element.

In the present embodiment, a semiconductor wafer 10 is produced which includes the terminals 7 formed right above the electrode pads 12 on the surface of the circuit thereof as described above. Then, the semiconductor wafer 10 including the terminals 7 having the above-described structure is divided into semiconductor chips 15 and 16 each including the terminals 7 having the above-described structure (see FIGS. 13A and 13B), as in the case of forming the terminals 7 having the above-described structure by the first terminal forming method.

Also, a semiconductor component 20 including the semiconductor chips electrically connected to each other (see FIG. 13D) may be produced as in the case of forming the terminals 7 having the above-described structure by the first terminal forming method. Thus produced semiconductor components 20 were subjected to high temperature storage test in a thermostatic oven of about 150° C. for evaluating the bonding of the terminals. As a result, it was confirmed that ten of ten samples had electrical continuity even after the storage test and thus exhibited improved reliability of bonding.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A terminal structure comprising:
a pillar containing a first metal material; and
a cover layer covering an upper surface and a side surface of the pillar, the cover layer containing a second metal material into which a solder material diffuses more slowly than into the first metal material.

2. The terminal structure according to claim 1, wherein the pillar contains Cu as the first metal material and the cover layer contains a metal selected from the group consisting of Ti, Cr, Ta, Al, W and Mo as the second metal material.

3. The terminal structure according to claim 1, further comprising:
a bonding layer over the cover layer, the bonding layer containing a metal material capable of solder bonding.

4. The terminal structure according to claim 3, further comprising:
a solder layer over the bonding layer.

5. The terminal structure according to claim 4, wherein the solder layer contains Sn.

6. The terminal structure according to claim 1, wherein the pillar contains Cu as the first metal material and the cover layer contains Ni as the second metal material.

7. The terminal structure according to claim 6, further comprising:
a solder layer over the cover layer.

8. The terminal structure according to claim 1, further comprising:
an oxide film covering the surface of the portion of the cover layer covering the side surface of the pillar.

9. A semiconductor device comprising:
a semiconductor chip including a first terminal including
a first pillar containing a first metal material, and
a first cover layer covering an upper surface and a side surface of the first pillar and containing a second metal material into which a solder material diffuses more slowly than into the first metal material; and
a substrate including a second terminal solder-bonded to the first terminal, the second terminal including
a second pillar containing a third metal material, and
a second cover layer covering an upper surface and a side surface of the second pillar and containing a fourth metal material into which the solder material diffuses more slowly than into the third metal material.

10. The semiconductor device according to claim 9,
wherein the first pillar contains Cu as the first metal material, and the first cover layer contains a metal selected from the group consisting of Ti, Cr, Ta, Al, W and Mo as the second metal material, and
wherein the second pillar contains Cu as the first metal material, and the second cover layer contains a metal selected from the group consisting of Ti, Cr, Ta, Al, W and Mo as the second metal material.

11. The semiconductor device according to claim 9,
wherein the first terminal and the second terminal are solder-bonded to each other, and the side surfaces of the solder-bonded first and second terminals are covered with an oxide film.

12. A terminal forming method, comprising:
forming a pillar containing a first metal material; and
forming a cover layer covering an upper surface and a side surface of the pillar and containing a second metal material into which a solder material diffuses more slowly than into the first metal material.

13. The terminal forming method according to claim 12, further comprising:
forming a solder layer right above the cover layer.

14. The terminal forming method according to claim 12, further comprising:
forming a bonding layer over the cover layer, the bonding layer containing a metal material capable of solder bonding,
wherein the cover layer contains a metal selected from the group consisting of Ti, Cr, Ta, Al, W and Mo as the second metal material.

15. The terminal forming method according to claim 14, further comprising:
forming a solder layer over the bonding layer.

16. The terminal forming method according to claim 12,
wherein the cover layer contains Ni as the second metal material.

17. The terminal forming method according to claim 16, further comprising:
forming a solder layer over the cover layer.

18. The terminal forming method according to claim 12, further comprising:
forming an oxide film over the surface of the portion of the cover layer covering the pillar.

19. The terminal forming method according to claim 12,
wherein the pillar contains Cu as the first metal material and the solder layer contains Sn.
